(19) United States
(12) Patent Application Publication
(10) Pub. No.: US 2013/0065350 A1
(43) Pub. Date: Mar. 14, 2013

(54) Thin Interdigitated Backside Contact Solar Cell and Manufacturing Process Thereof

(71) Applicant: Crystal Solar, Incorporated, Santa Clara, CA (US)

(72) Inventor: Kramadhati V. Ravi, Atherton, CA (US)

(73) Assignee: Crystal Solar, Incorporated, Santa Clara, CA (US)

(21) Appl. No.: 13/664,340

(22) Filed: Oct. 30, 2012

Related U.S. Application Data
(62) Division of application No. 12/290,582, filed on Oct. 31, 2008.

(51) Int. Cl. H01L 31/0236

(52) U.S. Cl. 438/71; 257/E31.13

(57) ABSTRACT

A design and manufacturing method for an interdigitated backside contact photovoltaic (PV) solar cell less than 100 μm thick are disclosed. A porous silicon layer is formed on a wafer substrate. Portions of the PV cell are then formed using diffusion, epitaxy and autodoping from the substrate. All backside processing of the solar cell (junctions, passivation layer, metal contacts to the N⁺ and P⁺ regions) is performed while the thin epitaxial layer is attached to the porous layer and substrate. After backside processing, the wafer is clamped and exfoliated. The front of the PV cell is completed from the region of the wafer near the exfoliation fracture layer, with subsequent removal of the porous layer, texturing, passivation and deposition of an antireflective coating. During manufacturing, the cell is always supported by either the bulk wafer or a wafer chuck, with no processing of bare thin PV cells.

### CROSS-REFERENCE TO RELATED APPLICATIONS

This application claims the benefit of U.S. Provisional Application Ser. No. 61/068,629, filed Mar. 8, 2008, which is expressly incorporated by reference herein.

### BACKGROUND OF THE INVENTION

1. Field of the Invention

This invention relates generally to the field of solar cell manufacturing, and more particularly to solar cells with interdigitated backside connections on very thin silicon wafers, for example, less than 50 microns in thickness

2. Description of the Related Art

There are two main types of photovoltaic (PV) cells used today. In the first type of PV cells, front side/back side connections are made through connecting ribbons soldered to bus bars to both the front and back of the PV cell. A disadvantage of this type of PV cell is the inevitable partial blockage of light entering the PV cell due to the front-side connections. In a second improved design for PV cells, all electrical connections to the PV cell diode are formed on the back surface of the PV cell through interdigitated back side connections. Thus, no light is blocked by the bus bars or connecting ribbons. A further advantage is the improved appearance of this type of cell—an important consideration for applications such as roof-mounted installations on residences.

Typically, prior art fabrication processes for photovoltaic (PV) cells use thick wafers having typical thicknesses of about 180 microns for the substrate. A sequence of furnace diffusion steps are then used to dope the various P-type and N-type regions in the PV cell, forming a diode structure in which electron-hole pairs are created by the photoelectric effect within the doped (either P or N-type) bulk material of the PV cell. FIGS. 20-23 illustrate a typical prior art PV cell design and fabrication process for an interdigitated backside contact PV cell. A blank wafer 2000 shown in FIG. 20 prior to a prior art PV cell fabrication process can be either P-type or N-type. As shown in FIG. 21, a prior art process diffuses boron or aluminum into P⁺ regions 2002 of the wafer 2000. If the wafer 2000 is P-type, then P⁺-P junctions 2004 are formed between the wafer 2000 at the P⁺ regions 2002. If the wafer 2000 is N-type, then P⁺-N junctions 2004 are formed between the P⁺ regions 2002 and the central part of the wafer 2000. In photovoltaic (PV) cell fabrication, typically furnace diffusion doping is used with the following processing steps to create P⁺ regions as is familiar to those skilled in the art: (1) the wafer surface is oxidized. (2) A patterned resist is deposited, typically using screen printing. (3) All oxide areas not covered by the patterned resist are wet etched to leave holes through the oxide exposing the surface of the P- or N-type wafer 2000. This wet etch step typically involves dipping the wafer 2000 into a hydrofluoric acid (HF) solution. (4) The patterned resist layer is stripped. (5) The dopant (typically either boron or aluminum) is diffused through the openings in the oxide layer. (6) Finally, the oxide layer is stripped.

As shown in FIG. 22, the prior art PV cell fabrication process then diffuses a dopant such as phosphorus between and adjacent to the P⁺ regions 2002. If the wafer 2000 is P-type, then N⁺-P junctions 2014 are formed. If the wafer 2000 is N-type, then N⁺-N junctions 2014 are formed. In photovoltaic (PV) cell fabrication, typically furnace diffusion doping is used with the following processing steps to create N⁺ regions as is familiar to those skilled in the art: (1) The wafer surface is oxidized. (2) A patterned resist is deposited, typically by screen printing. (3) All oxide areas not covered by the patterned resist are wet etched to leave holes through the oxide exposing the surface of the P- or N-type wafer 2000. This wet etch step typically involves dipping the wafer 2000 into a hydrofluoric acid (HF) solution. (4) The patterned resist layer is stripped. (5) The dopant (typically phosphorus) is diffused through the openings in the oxide layer. (6) Finally, the oxide layer is stripped.

As shown in FIG. 23, the prior art PV cell fabrication process then textures the upper surface of the wafer 2000, grows an N⁺-type layer 2020, grows an oxide'passivation layer 2022, and deposits an anti-reflective coating 2024. The passivation layer 2022 is intended to passivate or tie down dangling silicon bonds on the silicon surface so as to prevent recombination of the light-generated charge carriers at the surface to increase cell efficiency. The passivation layer 20022 may be composed of different kinds of materials, for example, silicon dioxide, undoped amorphous silicon, or silicon carbide. The first step includes the texturing, using a well known process, of the front surface of the PV cell to create a light scattering surface for the front of the PV cell. The second step is the growth of an N⁺ type layer 2020 by furnace diffusion, from the top, of phosphorus into the textured front surface of wafer 2000. During this second step, the bottom surface, including the P⁺ regions 2002 and the N⁺ regions 2012, is protected by a layer of oxide, typically thermally grown, to protect it from the N⁺ diffusion. Thus, the phosphorus dopant can only diffuse into the opposite top surface of wafer 2000 as shown. In the third step, an oxide passivation layer 2022 is grown on top of the N⁺-type layer 2020. Finally, an anti-reflective coating (ARC) 2024 is deposited on top of the oxide passivation layer 2022.

In FIGS. 20-23, the wafer 2000 is typically about 180 to 200 microns thick. The use of conventional, relatively thick solar cell wafers includes multiple steps, such as (1) converting trichlorosilane to solid silicon in a Siemens reactor, (2) melting and growth of a single crystal ingot from the resulting high purity silicon, (3) machining of the round ingot from the crystal growth process into quasi-square blocks, and (4) subsequent slicing of the blocks into thin wafers and the removal by chemical etching of slicing induced damage.

A disadvantage of this prior art PV cell fabrication process is the need for thick wafers and the resulting use of substantial amounts of silicon in the completed PV cell, raising materials costs. It would be desirable to fabricate PV cells with less thickness in order to decrease the usage of silicon, thereby reducing materials costs in the completed PV cell. Another disadvantage of this prior art PV cell fabrication process is the need for a large number of processing steps: (1) at least six steps to create the P⁺ regions 2002, (2) at least six steps to create the N⁺ regions 2012, (3) two steps to create the textured N⁺ region 2020, (4) a step to grow or deposit the oxide passivation layer 2022, and (5) a step to deposit the anti-reflective coating 2024.

It would be desirable to fabricate a PV cell using a process sequence with a smaller number of processing steps, thereby reducing costs and increasing fabrication yields.

A still further disadvantage of the use of furnace diffusion in the formation of the P⁺ regions 2002, and the two N⁺ regions 2012, 2020 is the relative lack of control over the dopant profiles (boron or aluminum for P⁺, and phosphorus for N⁺) as a function of depth into the wafer 2000 within the P⁺ and N⁺ regions 2002, 2012, and 2022. This lack of control is inherent in the furnace diffusion process, which relies on the thermal diffusion of dopants at high temperatures through the silicon lattice. In addition, at those areas on the surface of wafer 2000 which are not oxidized (and thus are open to dopant diffusion), precipitates of the dopant species typically form in a solid solution within the bulk silicon material of wafer 2000 adjacent the interface. In these areas, deleterious effects on the PV cell performance can result induced by excessive electron-hole recombination. Thus it would be desirable to employ a process for forming P⁺ and N⁺-type regions which has better control of dopant spatial distributions (profiles) as well as avoiding the formation of precipitates of the dopant species at the wafer surface during doping.

Since materials costs are a fundamental contributor to the overall costs of PV cells, reducing materials costs is clearly an important goal. Silicon wafers represent the major cost in the manufacture of solar cells so any reduction in the use of silicon and wafers, for example, by making them thinner, is desirable.

In one method for producing thin PV cells, a thin solar cell wafer is removed from a thicker mother wafer. In one such method, a damaged layer is created within the bulk wafer material using high energy (multiple MeV) implantation of hydrogen to damage the silicon structure at a known depth (determined by the ion energy). Following hydrogen implantation, the thin wafer may be peeled off the bulk wafer by exfoliation at the damaged layer, thereby separating the surface layer above the damaged layer from the thicker mother wafer. This method is expensive due to the need for high voltage implantation. In addition, the fabrication of the solar cell in this method requires a number of processing steps on the thin, exfoliated layer, for example, the steps of FIGS. 21-23. Such thin wafer processing can be extremely difficult with high breakage and damage rates and costly handling methods.

As is well known in the art of fabricating semiconductor integrated circuits, the high temperatures employed for epitaxial deposition may cause a simultaneous diffusion process with the wafer called “autodoping”. In normal semiconductor processing is at best a nuisance. Any potential deleterious effects for the transistors being fabricated are avoided by ensuring that the autodoped layer is sufficiently deep to be separated from those portions of the wafer in which the devices is fabricated.

### SUMMARY OF THE INVENTION

The present invention provides an improved design for an interdigitated backside contact thin photovoltaic (PV) cell fabricated on a thicker silicon mother wafer. For example, the cell may be less than 100 microns or preferably less than 75 microns or even less than 50 microns in thickness while the mother wafer may be 180 microns or greater in thickness.

Another aspect of the invention includes a fabrication process for manufacturing the improved PV cell design. The various aspects of the improved PV cell enable the following desirable features either singly or in combination.

One aspect of the invention includes epitaxial deposition of many or all of the semiconductor layers of the solar cell on a porous layer of a mother wafer and subsequent exfoliation of the epitaxial layer, thereby reducing use of silicon compared with the conventional thick wafer process. The epitaxial deposition on porous silicon for the formation of very thin silicon wafers also avoids the multiple energy-intensive steps characteristic of the conventional process of slicing a thick solar cell wafer from an ingot. The in situ formation of P⁺-P and N⁺-P junctions during epitaxial deposition processes also provides improved control of dopant profiles within the PV cell.

Another aspect of the invention includes processing the wafer while the thin, epitaxially-deposited layer is still attached to the underlying porous silicon layer and the thick silicon substrate through all the processing steps on one side of the wafer (which will be the back side of the completed PV cell), including oxidation, junction formation and contact formation.

In a further aspect of the invention includes attaching the partially completed solar cell to a chuck and exfoliating the cell from the mother substrate at the porous layer. In an extension of this aspect, all cell processing on the reverse side (front surface) of the cell, including texture etching, deposition of a passivation layer and an antireflection coating, for example, is completed while the cell is so chucked.

The invention allows processing with a limited number of steps, which is a substantial reduction in the number of processing steps compared with the prior art furnace diffusion fabrication method, thereby lowering manufacturing costs.

One embodiment of a process for practicing the present invention starts by creating a porous layer on one surface of a conventional thick silicon wafer on one surface, typically by an electrochemical etching process. After creation of the porous layer (typically 2 to 5 microns thick), the wafer may be is heated to cause sufficient thermal reflow or redistribution of silicon at the upper surface of the porous layer to enable high quality epitaxial growth of subsequent films.

Within an embodiment of the present invention, it is possible to employ epitaxial deposition to grow the necessary P- and N-type layers on top of a porous layer. It is well-known that the growth of films using epitaxial deposition affords high materials quality as compared with the conventional method of manufacturing layers in silicon wafers by furnace diffusion. In addition, with the formation of P-N junctions during epitaxial deposition, the possibility exists for much better control of dopant profiles when compared with dopant profiles generated using conventional furnace diffusion. This increased control arises from the epitaxial growth process allowing control of dopant concentrations in the material as it is deposited. This control is accomplished by the regulation and variation of the various feed gases during the epitaxial deposition process. Dopant profiles created in the bulk material by means of furnace diffusion, in contrast, are limited by the characteristics of thermal diffusion. In addition, at the surface, the formation of precipitates of the dopant species (e.g. phosphorus) may also occur, creating an undesirable layer which can cause loss of light-generated electrons near the surface of the solar cell. Thus, the use of epitaxial deposition for the growth of the necessary P- and N-type regions in the PV cell structure of the present invention affords many advantages over prior art PV cells structures fabricated using furnace diffusion.

Since the epitaxial growth process adds material (instead of doping a pre-existing crystal as in the diffusion doping process), it is possible to start the PV cell fabrication process from a porous layer on the surface of the wafer, not implanted deep in the wafer as is necessary for the process described above for the hydrogen implant method.

Another aspect of the present invention allows the advantageous use of autodoping to diffuse a dopant such as up from a thicker heavily doped mother wafer through the porous layer, and then up into the portion of the wafer destined to form the thin PV cell, is used to create a heavily doped front layer used to reflect electrons back towards the backside contacts.

Because the doping for the electron reflecting layer (which will be at the front of the completed PV cell) is accomplished simultaneously with the epitaxial growth the high temperatures employed for epitaxial deposition may cause a simultaneous diffusion process within the wafer called “autodoping”. Thereby, all separate processing steps required in the prior art fabrication process to create the electron reflecting layer may be eliminated, reducing the costs of PV cell manufacture.

The PV cell manufacturing method of one embodiment of the present invention employs epitaxial deposition to grow the P-type and N⁺ type layers of the PV cell while the cell is still attached to the bulk wafer. After growth of these layers, a significant number of cell processing operations are carried out while the thin silicon layer is still attached to the thick silicon substrate with a porous layer in between. Following this, the wafer may be clamped on the front side to a wafer chuck and then exfoliated. Within an embodiment of the present invention, it is possible to employ epitaxial deposition to grow the necessary P- and N-type layers on top of a porous layer. All subsequent processing steps are performed on the side of the wafer which had been in proximity to the porous layer at which this exfoliation occurs—this side will be the front side of the completed PV cell. Thus, no processing of the PV cell, either front-side or back-side, is performed without some means of solid mechanical support for the thin PV cell.

The P-type and N-type layers may be interchanged.

### BRIEF DESCRIPTION OF THE DRAWINGS

FIG. 1 is a schematic side cross-sectional view of a silicon wafer with a thin porous layer.

FIG. 2 is a schematic side cross-sectional view of the wafer from FIG. 1 with three epitaxial layers (P⁺-type, P-type, and N⁺-type), and a conformal passivation layer, grown on top of the porous layer.

FIG. 3 is a schematic side cross-sectional view of the wafer from FIG. 2 where a first patterned resist layer has been deposited, followed by an isotropic etch of the passivation and N⁺ epitaxial layers through the openings in the first patterned resist layer.

FIG. 4 is a schematic side cross-sectional view of the wafer from FIG. 2 showing an alternative laser ablation method for forming openings in the passivation and N⁺ epitaxial layers.

FIG. 5 is a schematic side cross-sectional view of the wafer from FIG. 3 or 4, where the first patterned resist layer has been removed (for the wafer from FIG. 3), followed by a boron diffusion through the openings in the oxide layer and the N⁺ epitaxial layer to form P⁺ regions in the P-type layer.

FIG. 6 is a schematic side cross-sectional view of the wafer from FIG. 5 where a second patterned resist layer has been deposited.

FIG. 7 is a schematic side cross-sectional view of the wafer from FIG. 6 where the passivation and N⁺ epitaxial layers have been isotropically etched through the openings in the second patterned resist layer, followed by removal of the second patterned resist layer.

FIG. 8 is a schematic side cross-sectional view of the wafer from FIG. 7 where an aluminum layer and a third patterned resist layer have been deposited.

FIG. 9 is a schematic side cross-sectional view of the wafer from FIG. 8 where the aluminum layer has been isotropically etched through the openings in the third patterned resist layer.

FIG. 10 is a schematic side cross-sectional view of the wafer from FIG. 9 where the third patterned resist layer has been removed, followed by deposition of a fourth patterned resist layer.

FIG. 11 is a schematic side cross-sectional view of the wafer from FIG. 10 where the passivation layer has been isotropically etched through the openings in the fourth patterned resist layer, followed by removal of the fourth patterned resist layer.

FIG. 12 is a schematic side cross-sectional view of the wafer from FIG. 11 where silver contacts have been screen printed both on the aluminum connections to the P⁺ regions and on the N⁺ epitaxial layer.

FIG. 13 is a schematic top view of a portion of the wafer from FIG. 12, illustrating the arrangement of the interdigitated contacts shown in the schematic side cross-sectional view in FIG. 13.

FIG. 14 is a schematic side cross-sectional view of the wafer from FIG. 13 attached to a chuck illustrating a laser ablation trimming operation of the wafer edges.

FIG. 15 is a schematic side cross-sectional view of the wafer from FIG. 14, showing the effects of the high intensity laser trimming operation in FIG. 14.

FIG. 16 is a schematic side cross-sectional view of the wafer from FIG. 15 during the exfoliation process.

FIG. 17 is a schematic side cross-sectional view of the portion of the wafer from FIG. 16 above the fracture surface, after the exfoliation process.

FIG. 18 is a schematic side cross-sectional view of the PV cell from FIG. 17 after removal of the partial porous layer from the bottom of the P⁺ layer, texturing of the upper surface of the P⁺ layer, growth of a thin conformal passivation layer on the textured P⁺ layer, and then deposition of an anti-reflective coating on the passivation layer.

FIG. 19 shows a completed PV cell with interdigitated backside connections.

FIG. 20 shows a blank wafer prior to a prior art PV cell fabrication process.

FIG. 21 shows the wafer from FIG. 20 after diffusion of P⁺ regions in a prior art PV cell fabrication process.

FIG. 22 shows the wafer from FIG. 21 after diffusion of N⁺ regions in a prior art PV cell fabrication process.

FIG. 23 shows the wafer from FIG. 22 after diffusion of an N⁺ layer, growth of an oxide layer, and deposition of an antireflective layer in a prior art PV cell fabrication process.

### DETAILED DESCRIPTION

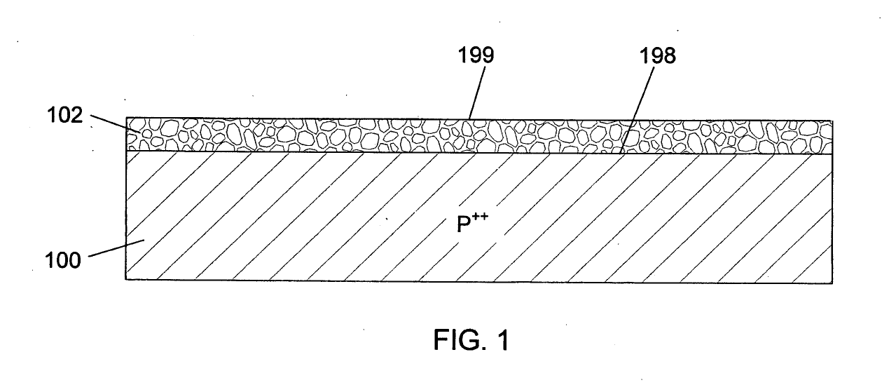

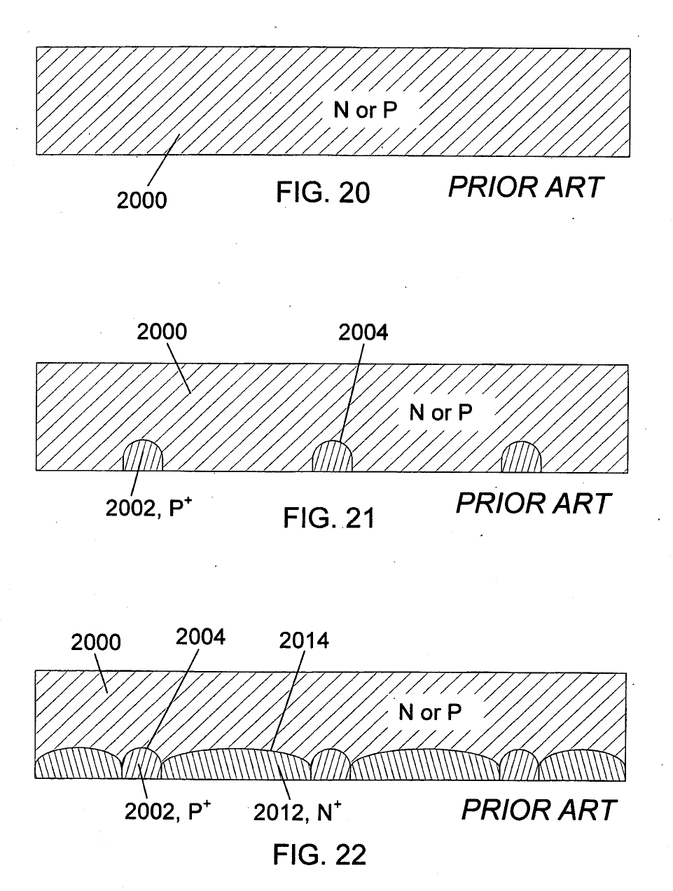

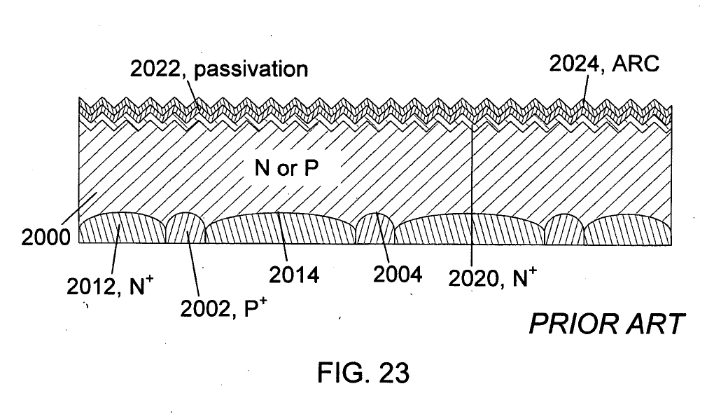

FIGS. 1 to 28 illustrate the steps in one embodiment of the fabrication process for a thin photovoltaic cell having interdigitated backside connections. Most figures are schematic side cross-sectional views in which the vertical dimensions are greatly enlarged relative to the horizontal dimensions. Note that this lack of scaling makes the profiles of the isotropic etch steps appear as vertical lines, since any undercutting occurring during the etch process cannot be seen when the vertical scale is greatly enlarged.

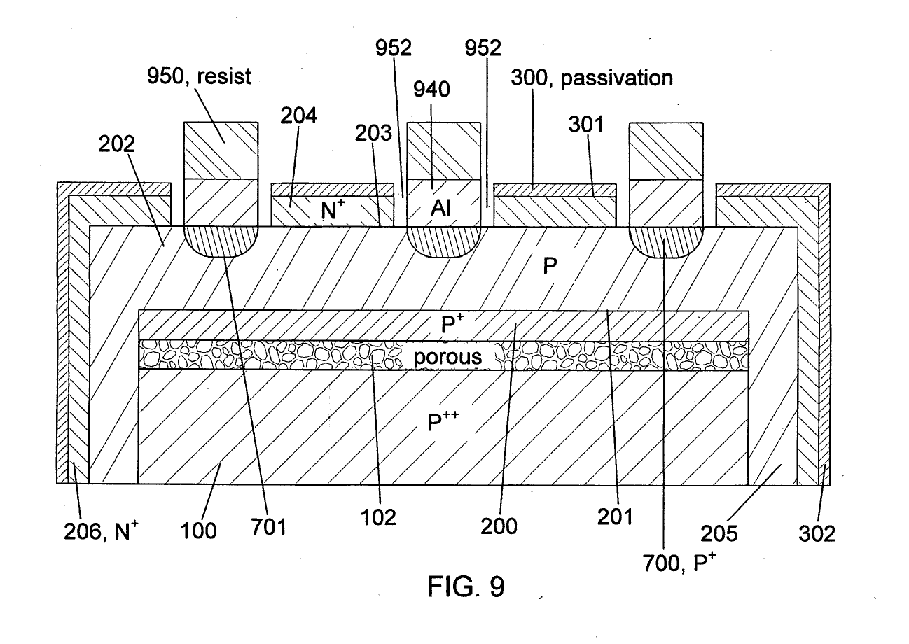

FIG. 1 is a schematic side cross-sectional view of a silicon wafer 100 with a thin porous silicon layer 102 at its upper principal surface. The wafer 100 may typically be P⁺⁺ boron-doped silicon with a resistivity in the range 0.01 to 0.005 ohm-cm. The tipper portion of the wafer 100 is made porous by using an anodic etching process, for example, using hydrofluoric acid (HF) as the electrolyte, as described in FIG. 9 of U.S. Provisional Patent Application Ser. No. 61/068,629, filed Mar. 8, 2008, thereby forming a porous layer 102, which has a typical thickness of 2 to 5 microns, and an interface 198 with the remaining non-porous wafer 100. The upper surface of wafer 100 is made porous by exposing it to an anodic etching process as illustrated in FIG. 9 of Ser. No. 61/068,629. The anodic etching forms pores in the surface of the wafer 100, thereby forming the porous layer 102, which has a typical thickness of about 1.0 μm. The pores are considered to extend generally vertically, to be distributed at low density across the surface, and to have diameters of about 0.5 to 2 nm although pore dimensions depend upon processing conditions. The low density allows the majority of the surface to retain the monocrystallinity characteristic of the mother wafer 100 to promote the subsequent epitaxial growth of silicon on the porous layer 102. After formation of the porous layer 102, the combined wafer 100 and porous layer 102 may be annealed in hydrogen to remove roughness on an upper surface 199 of the porous layer 102. During the anneal, silicon migrates and reorganizes across the upper surface 199 and tends to partially or fully close the tops of the pores in a monocrystalline structure while the pore diameter is being reduced to probably less than 0.5 nm. This smoothing process acts to provide a smooth generally monocrystalline surface for easy subsequent growth of epitaxial silicon. The silicon layers epitaxially grown over the porous layer 102 may include defects but the crystalline orientation from one lateral side to the other follows the monocrystalline orientation of the underlying monocrystalline silicon wafer 100 and the after grown layers should be substantially monocrystalline between the locations of the pores.

The solar cell of the invention relies upon the formation of different semiconductor layers forming semiconductor junctions. The description relies upon relative doping levels, which are inverse to resistivity levels. Although the invention is not limited to these values, typically P and N layers have resistivities of 0.5 to 10 ohm-cm, P⁺ and N⁺ layers have resistivities of 0.05 to 0.2 ohm-cm, and P⁺⁺ and N⁺⁺ layers have resistivities of 0.005 to 0.01 ohm-cm. Thus, the doping concentrations or resistivities differ by at least a factor of 2 and preferably by at least a factor of 10. The levels of doping of the N layers need not correspond numerically to the levels of doping of the P layers.

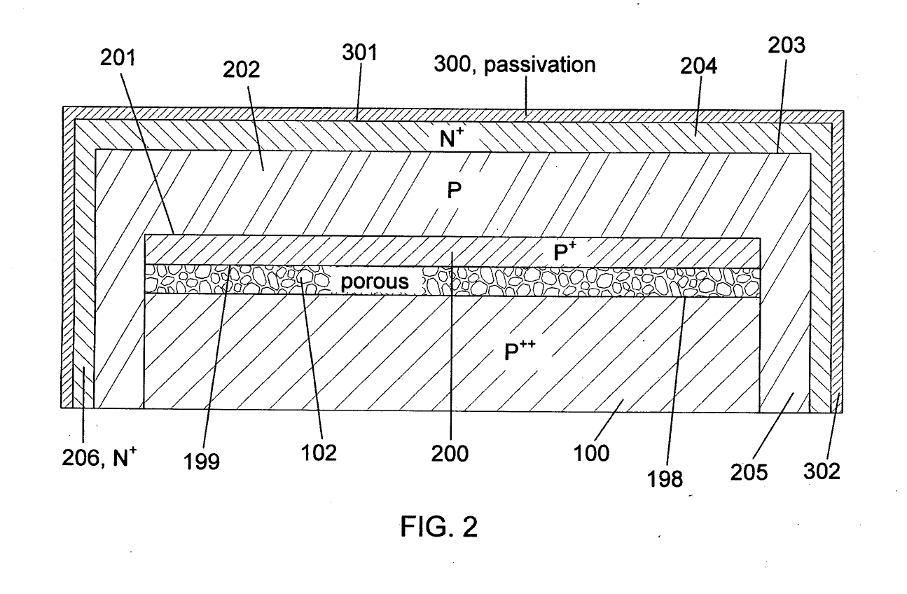

FIG. 2 is a schematic side cross-sectional view of the wafer from FIG. 1 with three epitaxial layers (P⁺-type 200, P-type 202 and N⁺-type 204) and a conformal passivation layer 300 on top of the porous layer 102. The boron-doped P-type monocrystalline layer 202 may be epitaxially grown directly on top of the porous layer 102. The typical thickness for the P-type layer 202 is 20 to 50 microns with a resistivity in the range 0.3 to 1.0 ohm-cm. During the high temperature epitaxial growth process of the P-type layer 202, boron diffuses upwards from the highly boron-doped wafer 100 and its similarly doped porous layer 102, forming within the P-type layer 202 the monocrystalline P⁺-type layer 200 between the porous layer 102 and the remaining portions of P-type layer 202 with a typical thickness of 0.3 micron. A P⁺-P junction 201 between the P⁺-type layer 200, and the P-type layer 202 is formed by this autodoping process during the epitaxial growth of the P-type layer 202. While the P-type layer 202 is forming on top of the porous layer 102, additional epitaxial growth is occurring around the sides of the wafer 100, forming a P-type side layer 205 which covers the edges of the wafer 100, the edges of the porous layer 102, and the edges of the P⁺-type layer 200. The P-type side layer 205 encloses the interface 199 between the porous silicon layer 102 and the P⁺-type layer 200. Again, the exaggeration of the vertical scale exaggerates the thicknesses of the side layers 205, 204, 302.

Next, the phosphorus-doped N⁺-type layer 204 is epitaxially deposited on top of the P-type layer 202. The monocrystalline N⁺-type layer 204 typically has a thickness in the range of 0.2 to 3.0 microns. An N⁺-P junction 203 is thereby formed between the P-type layer 202 and the N⁺-type layer 204. While the N⁺-type layer 204 is forming on top of the P-type layer 202, additional epitaxial growth is occurring around the sides of the wafer, forming an N⁺-type side layer 206 on top of the P-type side layer 205.

Finally, the conformal passivation layer 300, which may be an oxide of silicon, is grown on the top of the N⁺-type layer 204. The passivation layer 300 acts to couple to dangling silicon bonds in the N⁺-layer 204, which would act as recombination centers and degrade the semiconductor performance. While the passivation layer 300 is forming on top of the wafer, additional passivation layer growth is occurring on the N⁺-type side layer 206, forming a passivation side layer 302 at the edges of the wafer 100. The two oxide layers 300, 302 are typically 0.1 to 1.0 microns thick. There is a boundary 301 between the oxide layer 300 and the N⁺-type layer 204. One possible method for growing the oxide layers 300, 302 is thermal oxidation in an oven. Another possible method for growing the oxide layers 300 and 302 is rapid thermal oxidation (RTO) using incandescent lamps. Both oxidation methods are well-known to those skilled in the art. Alternative passivation materials are available, such as amorphous silicon and silicon carbide.

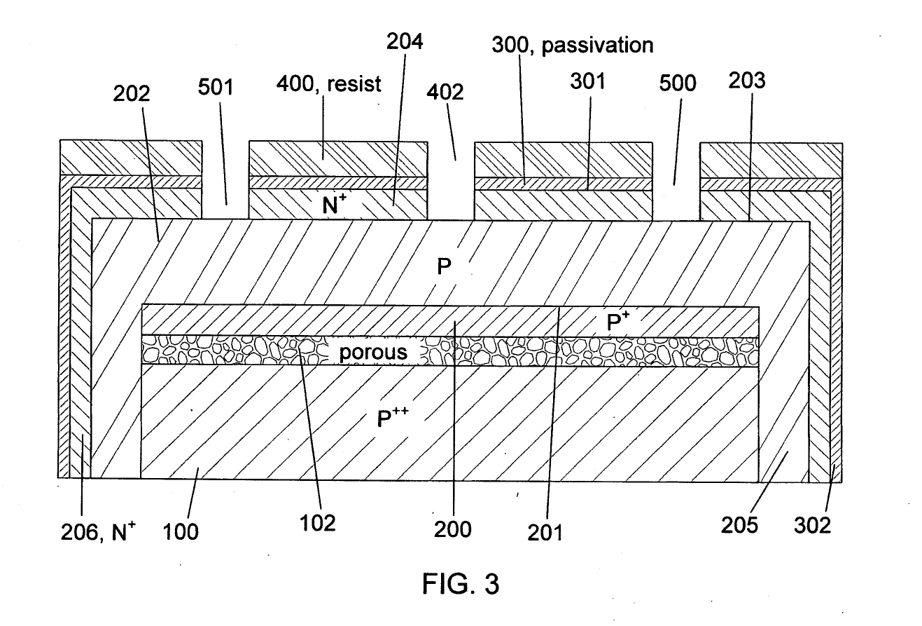

The schematic side cross-sectional view of FIG. 3 shows the wafer of FIG. 2 after three more process steps: (1) deposition of a patterned resist layer 400, (2) etching of openings in the passivation layer 300, and (3) etching of openings is the N⁺-type layer 204. In the first step, since the resist material is not readily etched, the openings 402 in the resist layer 400 will define diffusion areas for forming contacts in the next two processing steps. Standard, deposition techniques of relatively low resolution such as screen printing may be used to simultaneously form the patterned resist layer 400 and the openings 402 in the resist layer 400 and other similarly patterned resist layers. It is noted that the illustrated multiple holes 501, 500 are typically formed as narrow, long fingers extending out of the plane of the illustration, which are connected on the side of the solar cell to a common bus bar structure to form a single contact structure.

In the second and third steps, the pattern defined by the openings 402 in the resist layer 400 is etched through the passivation layer 300 and the N⁺-type epitaxial layer 204, respectively. If the etch process is isotropic, the openings 500 in the passivation layer 300 and the openings 501 in the N⁺-type epitaxial layer 204 may be slightly larger than the openings 402 in the resist layer 400. At the bottom of the openings 501 in the N⁺-type epitaxial layer 204, the P-type boron-doped layer 202 is exposed.

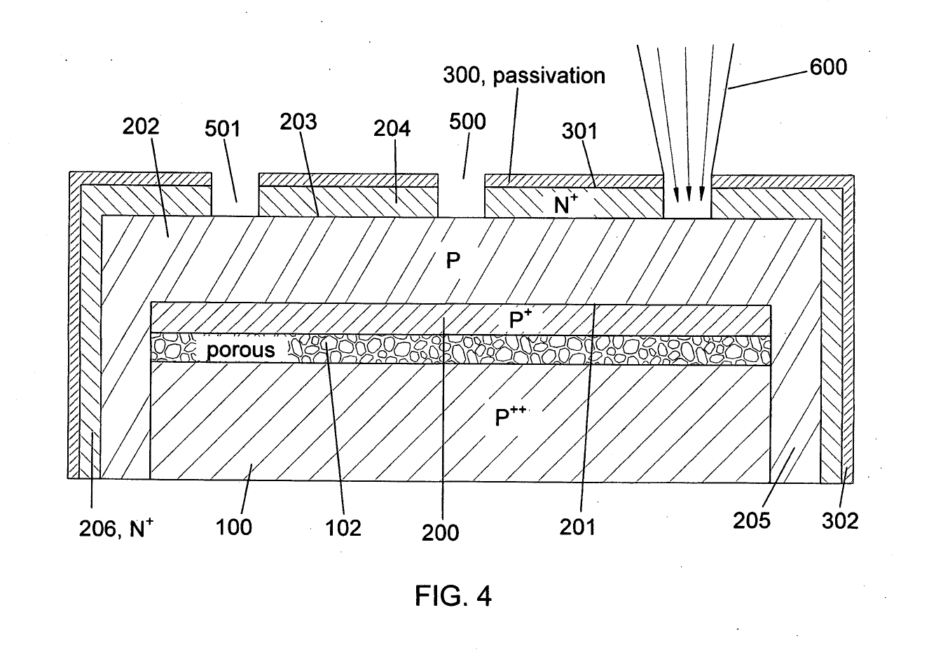

As shown in a schematic side cross-sectional view of FIG. 4, an alternative laser ablation method defines diffusion areas for the subsequent boron diffusion on the top of the wafer of FIG. 2. The laser ablation process eliminates the need for the patterned resist layer 400. Instead, a focused laser beam 600 is directed to each location where a contact is desired, as shown at the right of FIG. 4. The intense heat from the laser beam 600 evaporates holes 500 through the passivation layer 300 and then holes 501 through the N⁺-type epitaxial layer 204 stopping at the P-type layer 202. Contacts are thus written one at a time sequentially over the top surface of the passivation layer 300. Note that this process is an alternative to the multi-step process illustrated in FIG. 3.

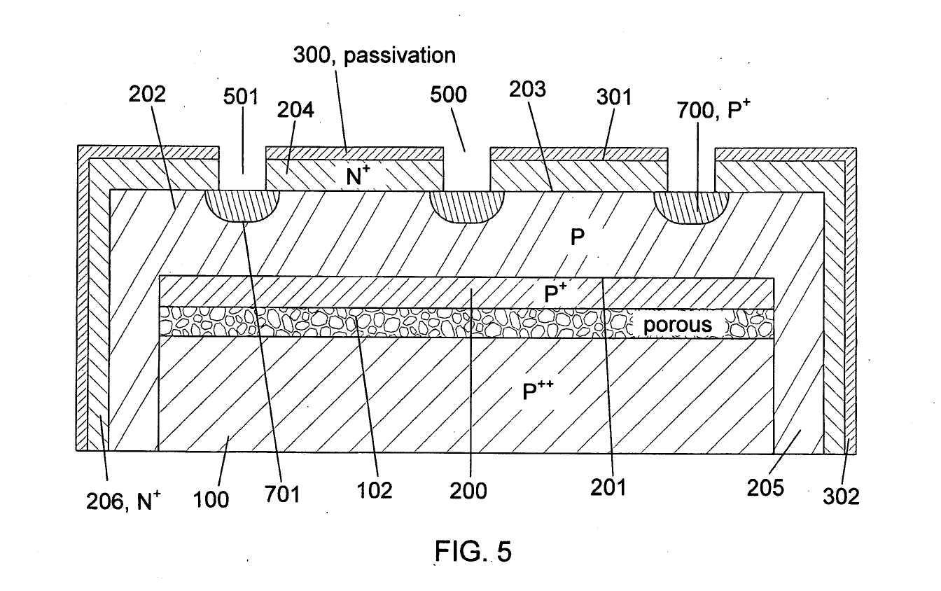

The schematic side cross-sectional view of FIG. 5 shows the wafer of FIG. 4 after three more process steps: (1) removal of the patterned resist layer 400, (2) diffusion of P⁺ regions 700 in the P-type layer 202, and (3) removal of a thin layer of borosilicate glass. In the first step in FIG. 5, the patterned resist layer 400 is removed using appropriate solvents as is familiar to those skilled in the art. The first process step in FIG. 5 is unnecessary for the laser ablation process illustrated in FIG. 4 since, for that process, no patterned resist layer 400 is needed.

In the second process step in FIG. 5, boron dopant is diffused through the openings 500 in the passivation layer 300 and the openings 501 in the N⁺-type epitaxial layer 204 to form P⁺ regions 700 in the P-type layer 202. The P⁺ regions 700 act to repel electrons back into the P-type layer 202, from which they will be collected at the other side. The boron diffusion process is generally isotropic within the P-type layer 202, forming P⁺ regions 700 which extend downwards into the P-type layer 202 and also sideways within the P-type layer 202 under the edges of the N⁺-type epitaxial layer 204. P⁺-P junctions 701 are thereby formed between the P⁺ regions 700 and the P-type epitaxial layer 202. After the boron diffusion process, it is typically necessary, in a third process step, to remove a thin layer of borosilicate glass from the upper surface of the P⁺ regions 700. This borosilicate glass forms during the high temperature boron diffusion process and must be removed prior to the deposition of patterned resist (see FIG. 9). This oxide removal process is much faster for the more heavily boron doped borosilicate glass than it is for the denser (and thus more etch-resistant) oxide layer 300.

The P⁺-P junction 201 and the P-P⁺ junction 701 are formed by the diffusion of dopants and thus present graded doping profiles near or across the junctions that are generally exponentially decreasing away from the dopant source where the exponential diffusion length is on the order of 0.1 to 0.3 microns. The exponential variation applies below the solubility limit, which is about 2*10²⁰/cm³ for phosphorus in silicon. Above the solubility limit, the excess dopant precipitates and forms a dead layer at the surface adjacent the source. On the other hand, the P-N⁺ junction 203 may be formed by two different steps of epitaxial deposition with different dopants and can be very abrupt. The doping profiles across the two layers 202, 204 can be relatively flat even approaching the solubility limit in the N⁺-layer 204, but then quickly change near the junction 203 over distances substantially less than the diffusion length associated with the other two junctions 201, 701.

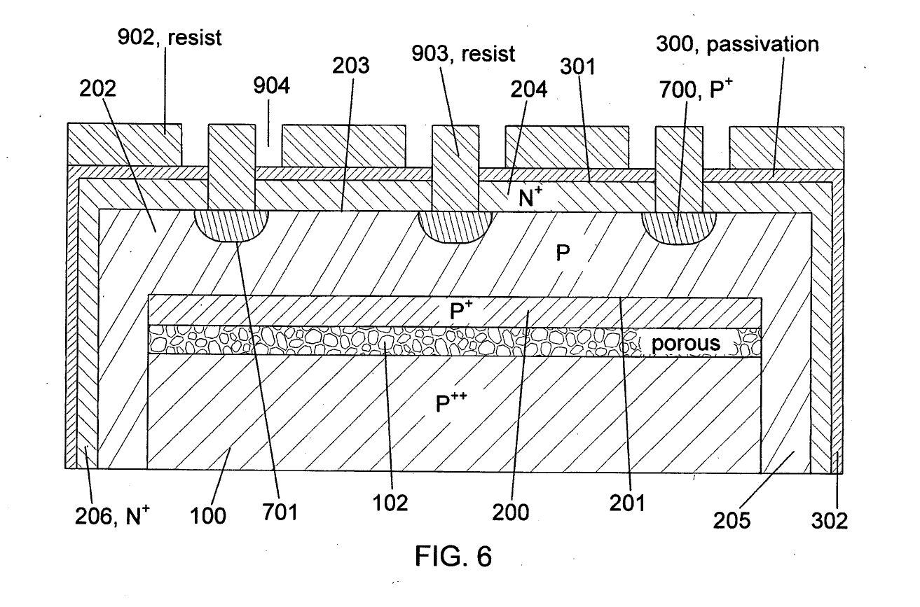

As shown in a schematic side cross-sectional view of FIG. 6, a patterned resist layer 902, 903 having openings 904 is deposited on the top of the wafer. Portions 903 of the patterned resist layer cover and fill the openings 500 in the passivation layer 300 and the openings 501 in the N⁺ type layer 204 (see FIG. 5). Portions 903 of the patterned resist layer cover the oxide passivation layer 300. Openings 904 in the resist layer lie between the resist portions 902 and 903, and extend down to the oxide passivation layer 300.

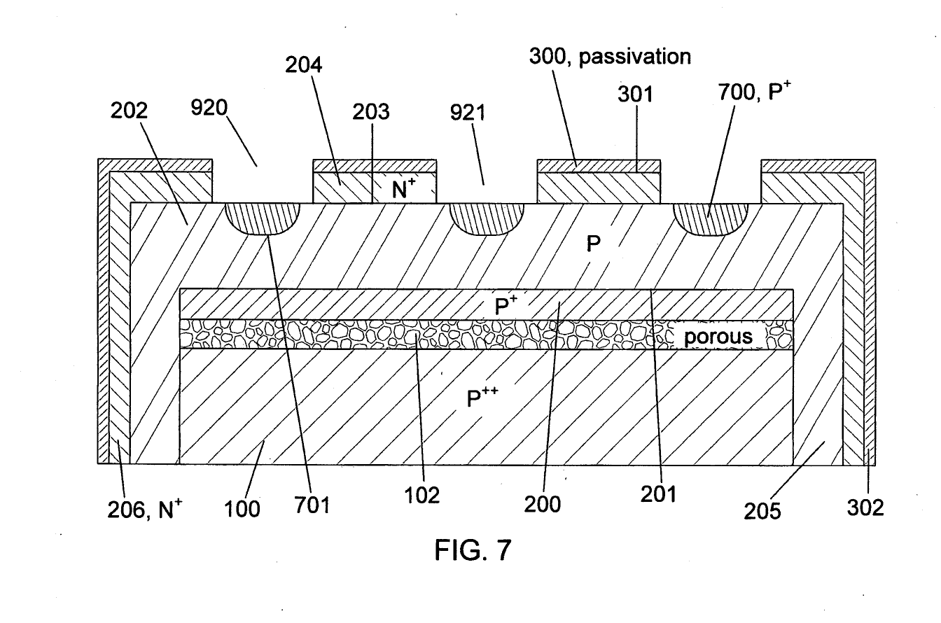

FIG. 7 is a schematic side cross-sectional view of the wafer from FIG. 6 after three more process steps: (1) etching of the passivation layer 300, (2) etching of the N⁺-type epitaxial layer 204, and (3) removal of the patterned resist layer 902 and 903. In the first and second process steps in FIG. 7, the pattern in the resist layer (at the openings 904 in the resist layer) masks an isotropic etch down through the oxide passivation layer 300 and the N⁺-type epitaxial layer 204, respectively, down to the P⁺ regions 700 and possibly the P-type layer 202. This etching process generates openings 920 in the passivation layer 300, and openings 921 in the N⁺-type epitaxial layer 204. If the etching process is isotropic, the openings 920, 921 in the passivation layer 300 and the N⁺-type epitaxial layer 204, respectively, will be somewhat larger than the openings 904 in the patterned resist layer 902, 903. The openings 921 in the N⁺-type epitaxial layer 204 electrically isolate the N⁺-type epitaxial layer 204 from the P⁺ regions 700. At the bottom of each opening 921 in the N⁺-type epitaxial layer 204, some of the P-type substrate 202 and the P⁺ region 700 are exposed. In the third process step of FIG. 7, the patterned resist layer 902 and 903 is removed to leave exposed the P⁺ regions 700 and the surrounding passivation layer 202. Removal of resist using appropriate solvents is familiar to those skilled in the art.

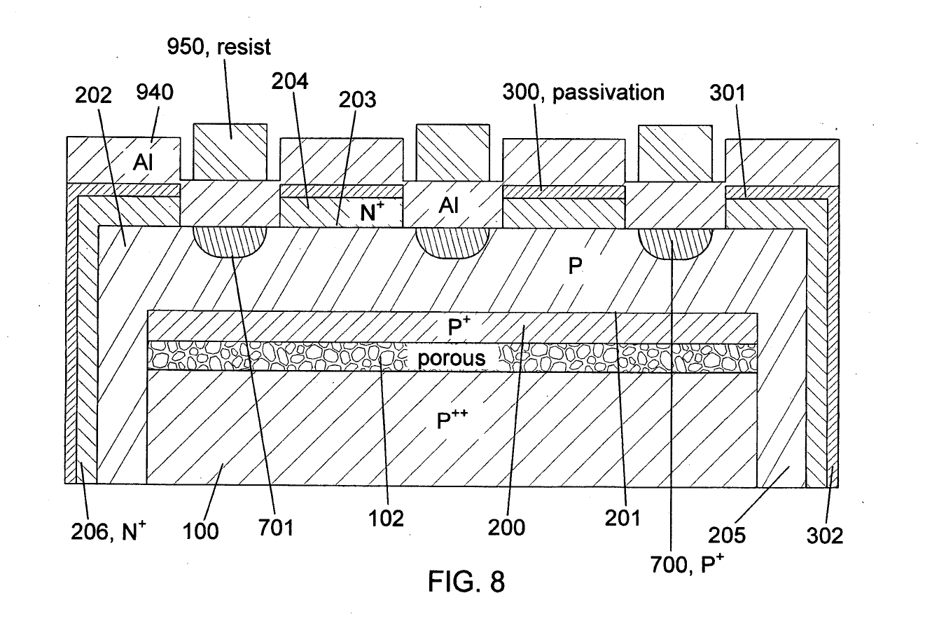

The schematic side cross-sectional view in FIG. 8 shows the wafer from FIG. 7 after three more process steps: (1) deposition of an aluminum layer 940, (2) sintering of the aluminum layer 940, and (3) deposition of a patterned resist layer 950. The aluminum layer 940 is one example of a conducting layer, which may be formed of different materials, for example, aluminum, a sandwich of titanium nitride with copper, or a sandwich of tantalum with copper. In the first process step in FIG. 8, an aluminum layer 940 is deposited, for example, by sputtering or evaporation, on the top of the wafer 100. Typically, the aluminum layer 940 has a thickness in the range of 1 to 4 microns. In the openings 920 in the oxide passivation layer 300 and in the openings 921 in the N⁺ epitaxial layer 204, the aluminum film 940 drops down as shown, with a step relative to the height of the film in the areas of aluminum film 940 on top of the passivation layer 300. The thicknesses of the aluminum layer 940 on top of the passivation layer 300 in the openings 920 in the oxide passivation layer 300 and the openings 921 in the N⁺ epitaxial layer 204 will generally be nearly the same; thus, the step height will approximately correspond to the combined thicknesses of the N⁺-type layer 204 and passivation layer 300. In the second process step of FIG. 8, the aluminum layer 941 is sintered such that those portions 941 of aluminum layer 940 filling the openings 921 in the N⁺ epitaxial layer 204 make good ohmic contact with the underlying P⁺ regions 700. In the third process step of FIG. 8, a patterned resist layer 950 is deposited on top of the portions of the aluminum layer 940 overlying the P⁺ regions 700 and spaced apart from the portions of the aluminum layer 940 overlying the passivation layer 300.

As shown in a schematic side cross-sectional view of FIG. 9, the patterned resist layer 950 masks an isotropic etch down through the aluminum layer 940. Those portions of the aluminum layer 940 overlying the passivation layer 300 and the P-type layer 202 are completely etched away. This etching process generates gaps 952 overlying the P-type layer 202 to thereby electrically isolate the remaining aluminum layer 940 and underlying P⁺ regions 700 from the N⁺-type layer 204.

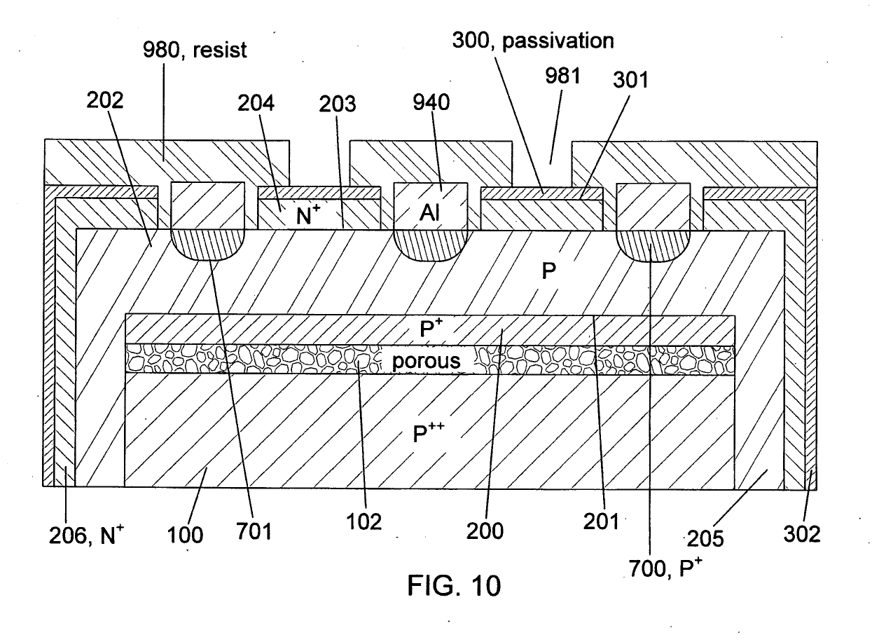

The schematic side cross-sectional view of FIG. 10 shows the wafer from FIG. 9 after two more process steps: (1) removal of the old patterned resist layer 950, and (2) deposition of another patterned resist layer 980. In the first process step of FIG. 10, the old patterned resist layer 950 is removed using appropriate solvents as is familiar to those skilled in the art. The relative height of the top of the aluminum layer 940 and the top of the oxide passivation layer 300 is determined by the amount of aluminum deposition in FIG. 8 relative to the combined thicknesses of the passivation layer 300 and the N⁺-type epitaxial layer 204. In the second process step of FIG. 10, the new patterned resist layer 980 with openings 981 is deposited on top of the aluminum layer 940, the oxide passivation layer 300, and the P-type layer 202. Openings 981 in the resist layer 980 define the locations of contacts to be formed to the N⁺ epitaxial layer 204 in subsequent processing steps.

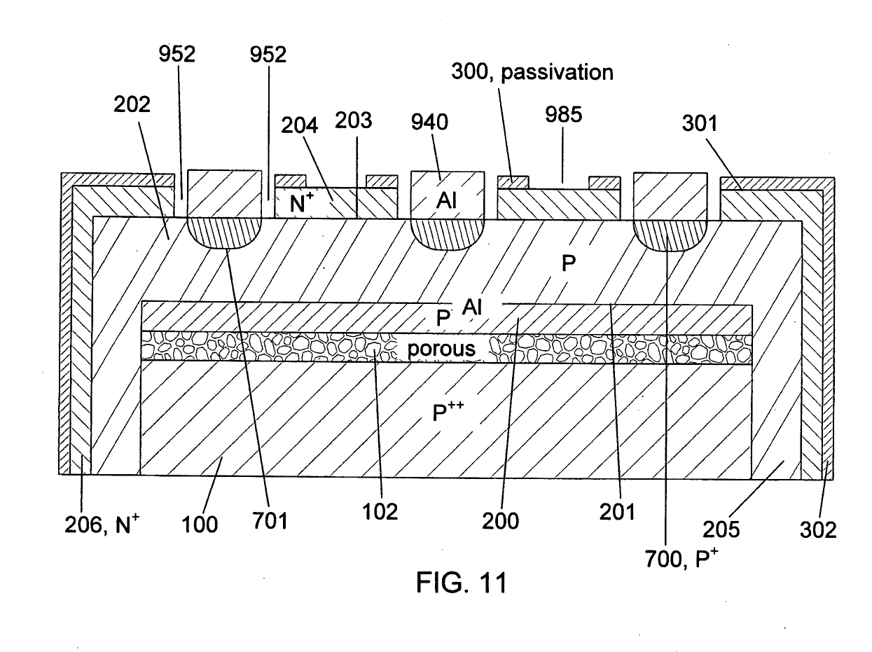

The schematic side cross-sectional view of FIG. 11 shows the wafer from FIG. 10 after two more process steps: (1) etching through the passivation layer 300, and (2) removal of the patterned resist layer 980 overlying the N⁺-layer 204. In the first process step of FIG. 11, the pattern in the resist layer 980 and its openings 981 serve as an etching mask for the passivation layer 300, thereby creating openings 985 in the passivation layer 300. At the bottom of the openings 985, center portions of the N⁺-type epitaxial layer 204 are exposed. In the second process step of FIG. 11, the patterned resist layer 980 is removed using appropriate solvents as is familiar to those skilled in the art.

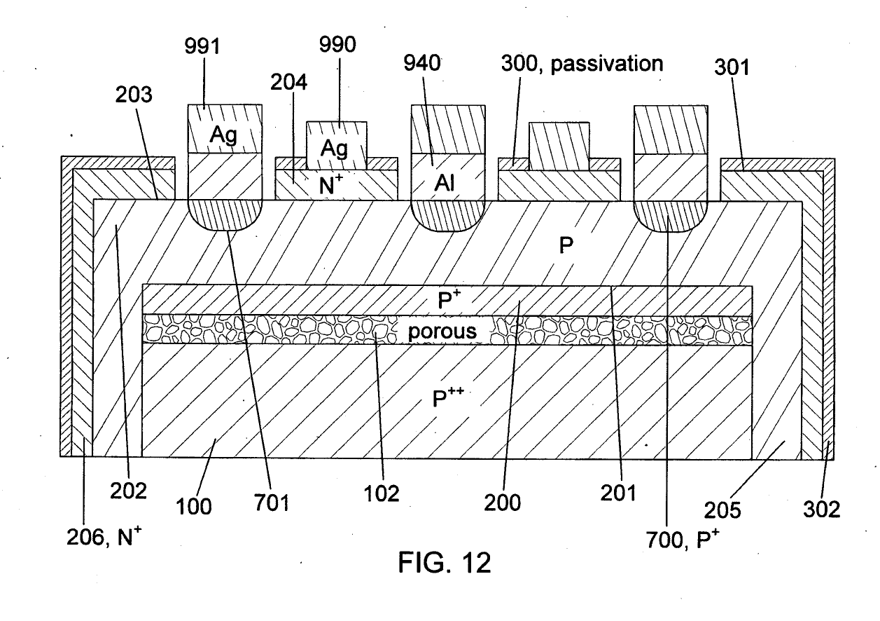

As shown in a schematic side cross-sectional view of FIG. 12, silver contacts 991 are printed on top of the aluminum layer 940 to make contact with the underlying P⁺ regions 700. Simultaneously, silver contacts 990 are screen printed through the openings 985 in the passivation layer 300 to make contact with the N⁺-type epitaxial layer 204. After the contact deposition, the wafer is annealed (sintered) the wafer to approximately 600 to 800° C. to densify and remove resin from the paste to form ohmic contacts between the silver contacts 991 and the aluminum layer 940, and between the silver contacts 990 and the N⁺-type epitaxial layer 204.

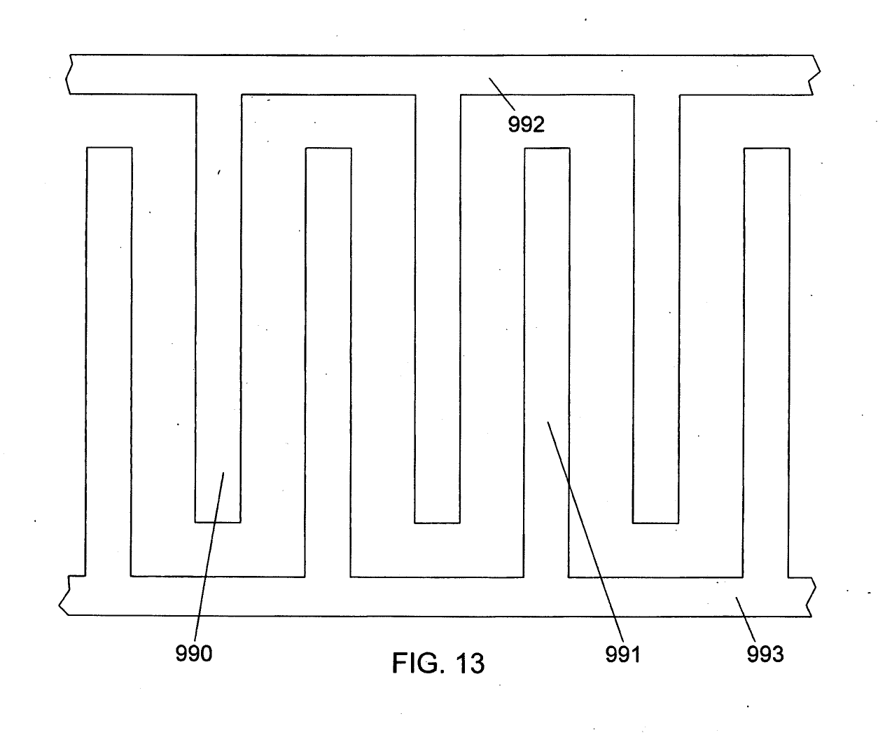

The schematic plan view of FIG. 13 shows the interdigitated contacts 990, 991 from FIG. 12 formed as thin, long fingers separated from each other in an interdigitated pattern. Holes arising from electron-hole pair generation by light within the P-type layer 202 are collected by the P contacts 991, connected through the aluminum layer 941 to the P⁺ regions 700. Electrons are collected by the N contacts 990, connected directly to the N⁺-type epitaxial layer 204. The performance of the photovoltaic cell is directly affected by the locations and spacings, as well as the thicknesses and widths, of the N contacts 990 and the P contacts 991. The optimum layout for the N and P contacts 990, 991 may be determined both theoretically and empirically as is familiar to those skilled in the art. Electron currents collected by N contacts 990 flow into an N bus bar 992 formed on one lateral side of the solar cell and then to the resistive load (not shown). Electron currents flowing through the load then flow into a P bus bar 993 formed on the other lateral side of the solar cell, next into the P contacts 991, and finally through the aluminum layer 940 to the P⁺ regions 700 where the electrons recombine with the holes flowing into the P⁺ regions 700 through the junctions 701 from the P-type region 202. The bus bars 992, 993, which are typically much wider than the finger-shaped contacts 990, 991, may be formed simultaneously with the contacts 990, 991 over the same underlying photovoltaic structure.

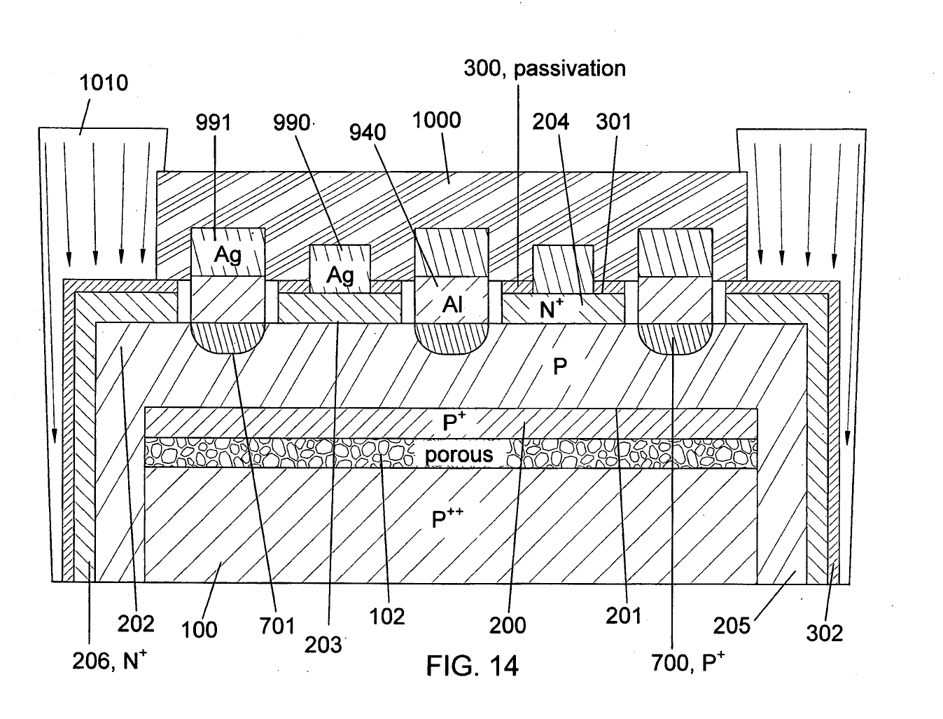

As shown in a schematic side cross-sectional view of FIG. 14, the wafer from FIG. 13 is attached to a chuck 1000. This attachment may be through electrostatic clamping, vacuum clamping, purely mechanical clamping, or a combination of these methods. Wafer clamping methods are familiar to those skilled in the art. The chuck 1000 may be designed as shown schematically in FIG. 14 to be slightly smaller than the overall dimensions of the wafer 100. A high power laser beam 1010 may be used to cut around the full perimeter of the wafer outside the contacts 990, 991 and bus bars 992, 993, thereby removing the passivation side layer 302, the N⁺-type epitaxial side layer 206, and the P-type side layer 205 on the top and side perimeter of the wafer 100. In addition, a small portion of the edges of the P-type layer 202, the P⁺ layer 200, the porous layer 102, and the wafer 100 may be cut away by the laser beam 1010. This cutting process removes the undesirable side layers which would make the subsequent exfoliating operation difficult.

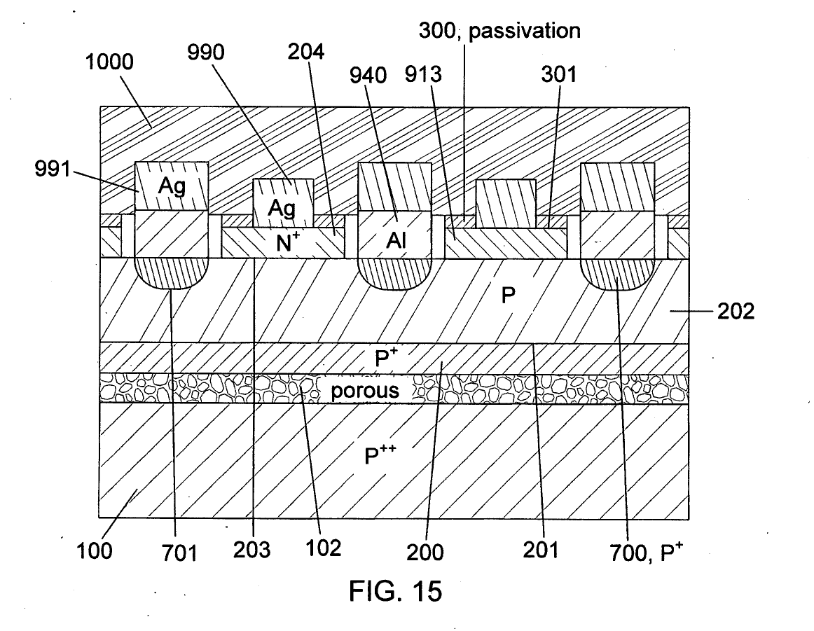

The schematic side cross-sectional view of FIG. 15 shows the effects of the high intensity laser trimming operation in FIG. 14. Now, all the edges of the wafer 100, the porous layer 102, the P⁺-type layer 200, the P-type layer 202, the N⁺-type layer 204, and the passivation layer 300 are exposed and the photovoltaic wafer being fabricated now has the desired final X-Y dimensions, where the X and Y axes are in the plane of the wafer 100. An alternative method for trimming the wafer is to use dicing saws. Both methods of trimming are familiar to those skilled in the art.

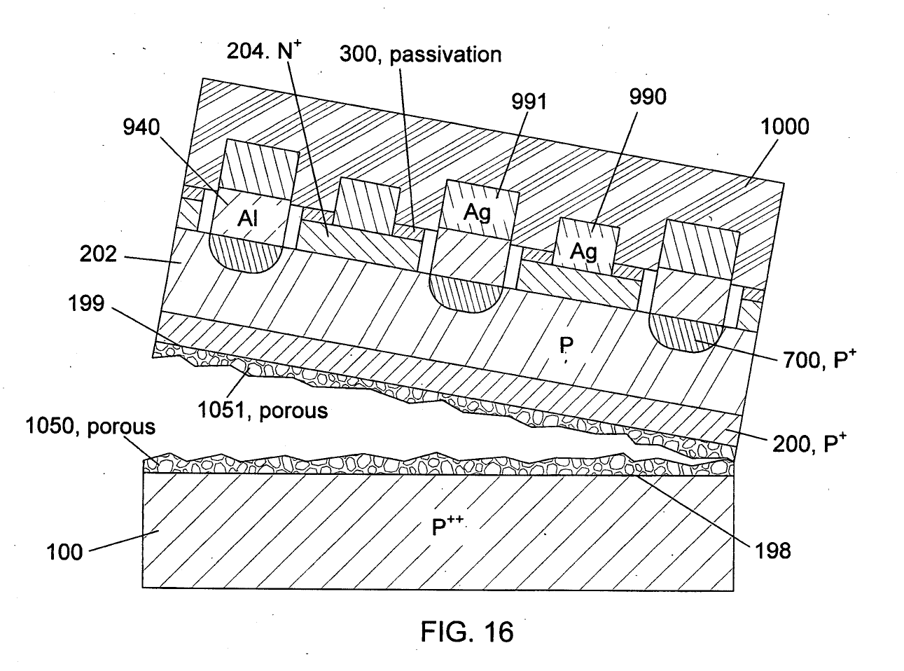

The schematic side cross-sectional view of FIG. 16 shows the wafer from FIG. 15 during an exfoliation process, as described in Ser. No. 61/068,629. The bottom of the wafer 100 is held down using electrostatic, vacuum or mechanical clamping. Since the wafer 100 will be relatively thick (>200 μm), the wafer 100 will be too stiff to undergo appreciable bending during the exfoliation process. The chuck 1000 must have some degree of flexibility, either by means of flexible material used to fabricate the chuck 1000, or by segmentation of stiff elements comprising the chuck 1000. Thus, the chuck 1000 will support a means of exfoliating the fabricated PV cell being manufactured. An upward force, and possibly also a torque, are applied to the chuck 1000, causing the porous layer 102 to progressively fracture from the left to the right of FIG. 16, leaving a first partial porous layer 1050 attached at an interface 198 to the wafer 100, and a second partial porous layer 1051 attached at an interface 199 to the bottom of the P⁺-type layer 200. The described exfoliation process involves a mechanical fracturing process. Chemical etch exfoliation processes are known and may be used alone or in combination with the mechanical process.

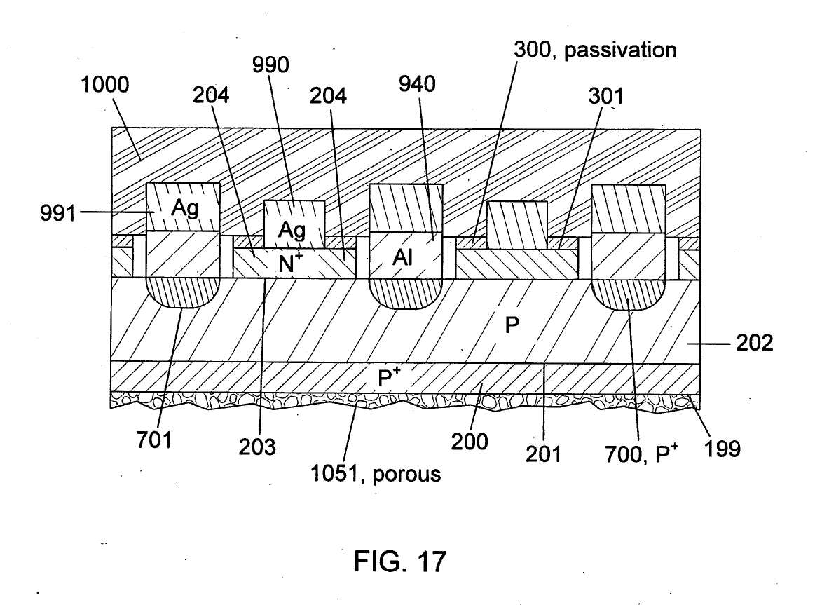

A schematic side cross-sectional view of the PV cell being manufactured is shown in FIG. 17 after the exfoliation process of FIG. 16. A partial porous layer 1051 remains attached at an interface 199 to the bottom of the P⁺-type layer 200.

In a separate set of steps, the partial porous layer 1050 is removed from the mother wafer 100, which may then be used to grow another thin solar cell wafer by the previously described steps of anodically etching a porous layer, etc. The mother wafer can be used for many generations of solar cells until it finally becomes too thin. The reuse of the thick wafer greatly reduces materials cost.

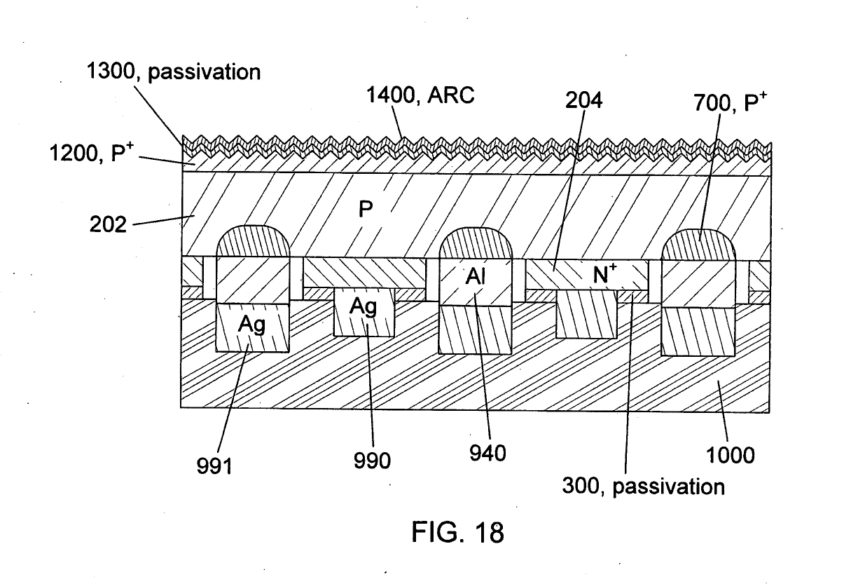

The schematic side cross-sectional view of FIG. 18 shows the PV cell of FIG. 17 after four more process steps: (1) removal of the partial porous layer 1051, (2) texturing of the upper surface of the P⁺-type layer 200, (3) growth of a thin passivation layer 1300, and (4) deposition of an antireflective coating 1400. The first process step in FIG. 18 is the removal of the partial porous layer 1051 from the bottom of the P⁺-type layer 200, for example using a liquid etchant of hydrofluoric acid and hydrogen peroxide.

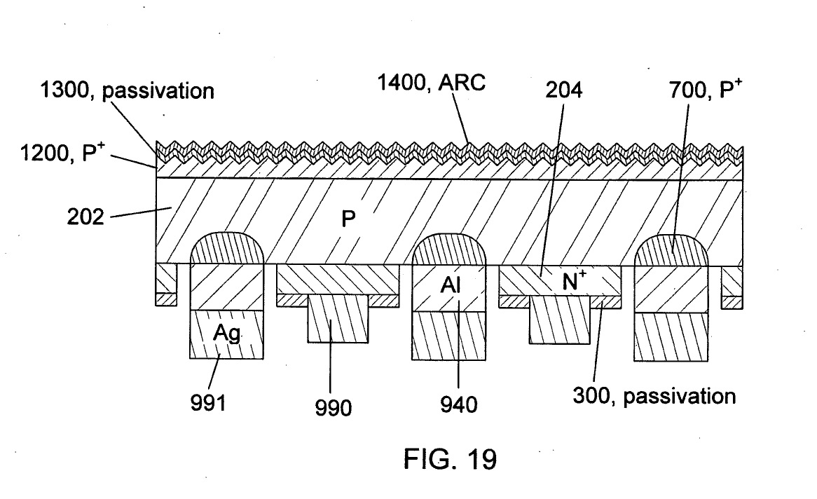

Note that all subsequent processing steps will be on the side of the wafer which was previously attached to the wafer 100 through the porous layer 102. Thus, the PV cell being fabricated is shown rotated 180° in FIGS. 18 and 19 relative to its orientation in FIG. 17. Due to the porosity of the partial porous layer 1051, the etch rate of the porous layer 1051 is substantially higher than the etch rate of the P⁺-type layer 200, which is dense, epitaxially grown boron-autodoped crystalline silicon. Silicon etch rates are highly density-dependent.

In the second process step in FIG. 18, the P⁺-type layer 200 is texture etched to form a textured P⁺-type layer 1200 to enhance light collection efficiency in the completed PV cell. Typically, a wet etch chemistry of KOH and isopropyl alcohol is used. It is also possible to do texture etching using a plasma etch process with fluorocarbon etchant gases. The result of the texture etch is to form a textured P⁺-type layer 1200 with a rough surface 1201 from at least a portion of the P⁺-type layer 200.

The third process step in FIG. 18 is the growth of a thin (about 0.1 microns thick) passivation layer 1300 on the surface 1201 of the textured P⁺-type layer 1200 using, for example, a rapid thermal oxidation process to oxidize the underlying textured P⁺-layer 1200. An alternative method for the passivation of the P⁺-type layer 200 is the deposition of amorphous silicon using a plasma-enhanced chemical vapor deposition (PECVD) process. Both methods for forming passivation layers are familiar to those skilled in the art. The fourth process step in FIG. 18 is deposition of an anti-reflective coating (ARC) 1400 on the passivation layer 1300. A typical anti-reflective coating is a silicon nitride (SiNₓ) film roughly 0.09 microns thick. Either PECVD or physical vapor deposition (PVD) techniques may be used to deposit the anti-reflective coating 1400 as is familiar to those skilled in the art.

Several of the thus fabricated solar cells are typically interconnected in series between the bottoms of bottom of adjacent cells to form a string to build up the voltage to a convenient operational level. A multitude of these strings are then placed by appropriate robotics on a layer of, for example, ethylene vinyl acetate (EVA) on top of a backing material, typical a polymer available form DuPont called Tedlar supported on a lay up table with the contact grids on the bottom and the their textured light-receiving sides facing upwardly. The strings are attached together through connecting straps of solder-coated copper to produce parallel connected strings. Another layer of EVA is placed on the string array followed by a glass sheet. The entire assembly is put into an autoclave or lamination chamber to laminate the assembly to complete the manufacture of the solar module.

It is noted that in the described process no processing performed after exfoliation involves epitaxial growth of silicon. All epitaxial growth is performed on the preferably smoothed porous layer attached to the stiff, monocrystalline mother wafer.

FIG. 19 is a schematic side cross-sectional view of the wafer from FIG. 18 after declamping from the wafer chuck 1000, showing the completed thin interdigitated backside connection photovoltaic solar cell of the present invention.

It will be understood by those skilled in the art that the foregoing descriptions are for illustrative purposes only. A number of modifications to the above fabrication sequence and PV cell design are possible within the scope of the present invention, such as the following.

Alternative methods of etching through the oxide layer 300 and the N⁺-type epitaxial layer 204 are possible instead of wet etching, including Reactive Ion Etching (RIE), or laser ablation. In the RIE process, the plasma contains chemical species (both ions and radicals) which react with the oxide layer 300 and then with the N⁺ epitaxial layer 204 after the oxide layer 300 has been etched away in a two-step etching process. Two different plasma etch chemistries may be used for the oxide layer 300 and the N⁺ epitaxial layer 204. Both wet and dry (plasma) etch methods for oxide and N⁺-type silicon are well known to those skilled in the art and are not part of the present invention.

Alternative methods for removing resist instead of a wet solution are possible. Plasma ashing processes may also be used to selectively remove resist. Both wet and dry (plasma) processes for resist removal are well known to those skilled in the art and are not part of the present invention.

Alternatives to the use of screen printing of patterned resist layers is possible. A continuous film of resist may be deposited and subsequently patterned using photolithography. Both of these resist patterning methods are familiar to those skilled in the art and are not part of the present invention.

The described process affords improved fabrication yields through reduced breakage during processing due to the reduced number of processing steps and new approaches for handling very thin silicon wafers thru various processing operations.

It further substantially reduces materials costs by the deposition of active silicon layers on reusable mother wafers. The epitaxial deposition of these layers provides better control of the doping profiles and allows the formation of sharp photovoltaic junctions.

1-12. (canceled)

13. A method of fabricating a backside contact solar cell, comprising the steps of:
a first deposition step of epitaxially growing a first film of silicon of a first conductivity type on a porous layer formed in silicon wafer;
a second deposition step of epitaxially growing a second film of silicon of a second conductivity type on the first film to thereby forming a P-N junction therebetween;
while the films are attached to the porous layer, a first forming step of forming first electrical contacts to the first layer and a second forming step of forming second electrical contacts to the second layer.

14. The method of claim 13, wherein the wafer is of the first conductivity type more heavily doped than the first film and wherein the first deposition step causes autodoping to form a third film in the first film adjacent the porous layer which is more heavily doped than a remainder of the first film.

15. The method of claim 13, further comprising the subsequent step of exfoliating the films from the wafer.

16. The method of claim 15, further comprising the subsequent step of texturing a surface of the first film.

17. The method of claim 15, further comprising depositing a passivation and anti-reflection layer on the textured surface.

18. A method for fabricating a thin interdigitated backside contact photovoltaic solar cell on a thick wafer, comprising the steps of:
A. epitaxially growing a first layer of silicon of a first conductivity type on an upper surface of a porous crystalline silicon layer formed on a monocrystalline silicon substrate;
B. epitaxially growing a second layer of silicon on the upper surface of the first layer;
C. forming a first passivation layer on top of the second layer;
D. etching first openings through selected areas of the passivation and second layers;
E. forming contact regions within the second layer which are of the second conductivity type and more heavily doped than the second layer, wherein the dopant species to form the contact regions is diffused through the first openings;
F. etching second openings surrounding the first openings through the passivation and second layers;
G. depositing a conducting layer;
H. etching the conducting layer to remove portions not overlying the contact regions; and
I. etching second openings through the first passivation layer overlying central areas of the second layer.

19. The method of claim 18, wherein the first conductivity type is P-type.

20. The method as in claim 18, further comprising a step of depositing conducting first contacts on top of the conducting layer and conducting second contact in second openings, wherein the first contacts are isolated from the second contacts.

21. The method as in claim 20, wherein the first contact are connected together by a first bus bar and are interdigitated with the second contacts, which are connected together by a second bus bar.

22. The method as in claim 18, further comprising a step of cutting away portions of the first, second, and passivation layers on the side edges of the wafer.

23. The method as in claim 20, further comprising:
clamping an upper surface of the solar cell with a wafer clamp; and
separating at the porous layer the first and second layer and structure formed thereover from the wafer in an exfoliation process.

24. The method as in claim 23, wherein said exfoliation process comprises a mechanical fracturing process.

25. The method as in claim 23, wherein said exfoliation process comprises a chemical etch process.

26. The method as of claim 23, wherein the steps of claim 18 are repeated for the wafer produced by the separating step of claim 23.

27. The method as in claim 23, further comprising texturing the third layer.

28. The method as in claim 27, further comprising forming of a passivation and anti-reflection layer on top of the textured third layer.

29. The method as in claim 18, wherein said porous layer is formed by electrochemical etching.

30. The method as in claim 29, wherein the porous layer is smoothed by rapid thermal processing.

31. The method as in claim 18, wherein said conducting layer is aluminum.
